(19) United States
(12) Patent Application Publication
(10) Pub. No.: US 2025/0178885 A1
(43) Pub. Date: Jun. 5, 2025

(54) MICROELECTROMECHANICAL MOTION SENSOR DEVICE HAVING A SINGLE PROOF MASS

(71) Applicant: STMicroelectronics International N.V., Geneva (CH)

(72) Inventors: Massimiliano PESATURO, Torre De' Roveri (IT); Bruno MURARI, Monza (IT); Stefano BOSCO, Gessate (IT); Manuel RIANI, Como (IT); Paolo PESENTI, Senago (IT)

(73) Assignee: STMicroelectronics International N.V., Geneva (CH)

(21) Appl. No.: 18/961,380

(22) Filed: Nov. 26, 2024

(30) Foreign Application Priority Data
Dec. 5, 2023 (IT) 102023000026001

(51) Int. Cl. B81B 3/00

(52) U.S. Cl. CPC B81B 3/0062; B81B 2201/0221; B81B 2201/0235; B81B 2203/0172; B81B 2203/04; B81B 2203/053; B81B 2203/058

(57) ABSTRACT

A microelectromechanical motion sensor device is described, provided with: a base substrate having a front surface with extension in a horizontal plane; and a sensing structure arranged above the base substrate, for sensing components of a motion quantity along respective sensing axes. The sensing structure is provided with: a housing element integrally coupled above the front surface of the base substrate and internally defining a cavity; a single mobile mass arranged inside the cavity; an elastic supporting arrangement arranged above the mobile mass, with main extension in a plane overlying the mobile mass to elastically support the mobile mass inside the cavity, so that it is suspended above the front surface of the base substrate and performs, due to inertial effect, a respective sensing movement in response to each of the components of the motion quantity; and a sensing electrode arrangement, capacitively coupled to the mobile mass for sensing the components of the motion quantity.

### BACKGROUND

### Technical Field

The present solution relates to a microelectromechanical (MEMS, Micro-Electro-Mechanical System) motion sensor device, having a single proof mass.

### Description of the Related Art

Motion sensors are known, in particular accelerometer sensors, made with micromanufacturing techniques, which envisage use of mobile masses or inertial masses (so-called “proof masses”), elastically supported with respect to a substrate to perform one or more movements due to inertial effect in response to respective components of a quantity (for example, an acceleration) to be sensed along one or more sensing axes.

The mobile masses are typically supported by elastic elements (or simply “springs”) configured to allow the sensing movements and define the sensing axes of the motion sensor device.

The known motion sensor devices and the corresponding sensing structures, especially due to the presence of multiple mobile masses for sensing the quantities of interest, may however have some limitations and issues, for example as to the manufacturing complexity and the associated costs; the dimensions; the presence of possible couplings and interferences between the sensing axes (so-called “cross-axis” interferences); and detection sensitivity.

### BRIEF SUMMARY

The present disclosure provides a solution to overcome the limitations of known devices.

According to the present solution, a microelectromechanical motion sensor device is provided. A microelectromechanical motion sensor device comprises a base substrate having a front surface opposite a second surface along a first direction; and a sensing structure on the front surface of the base substrate, the sensing structure being configured to detect components of a motion quantity along a plurality of sensing axes. The sensing structure includes a housing element coupled to the front surface of the base substrate and including a cavity, the housing element including a frame element; a single mobile mass arranged inside the cavity, the frame element surrounding the mobile mass; and an elastic supporting arrangement coupled to the mobile mass and extending in a plane opposite the mobile mass from the front surface along the first direction, the elastic supporting arrangement configured to elastically support the mobile mass inside the cavity, the mobile mass being suspended opposite the front surface of the base substrate, the mobile mass performing, due to an inertial effect, a respective sensing motion in response to each of the components of the motion quantity. The elastic supporting arrangement includes a plurality of elastic elements anchored to the frame element and a coupling element with a first dimension along the first direction, the coupling element being coupled between the mobile mass and the plurality of elastic elements. The sensing structure further includes a sensing electrode arrangement, capacitively coupled to the mobile mass for sensing the components of the motion quantity.

### BRIEF DESCRIPTION OF THE SEVERAL VIEWS OF THE DRAWINGS

For a better understanding of the present disclosure, a preferred embodiment thereof is now described, purely by way of non-limiting example and with reference to the attached drawings, wherein:

FIG. 1A shows a perspective view of a microelectromechanical motion sensor device according to an embodiment of the present solution;

FIG. 1B is a perspective view of a base substrate of the device of FIG. 1A;

FIG. 1C is a perspective view of a sensing structure of the device of FIG. 1A;

FIG. 2 is a schematic view of a first sensing electrode arrangement of the device of FIG. 1A, with a corresponding differential sensing circuit scheme; and

FIG. 3 is a schematic view of a second sensing electrode arrangement of the device of FIG. 1A, with a corresponding differential sensing circuit scheme.

### DETAILED DESCRIPTION

As will be described in detail below, one aspect of the present solution relates to manufacturing of a microelectromechanical (MEMS) motion sensor device having a single sensing mass (or proof mass), for sensing multiple components of a motion quantity to be sensed, for example an acceleration, in particular components of this quantity along three sensing axes of a reference system associated with the same motion sensor device.

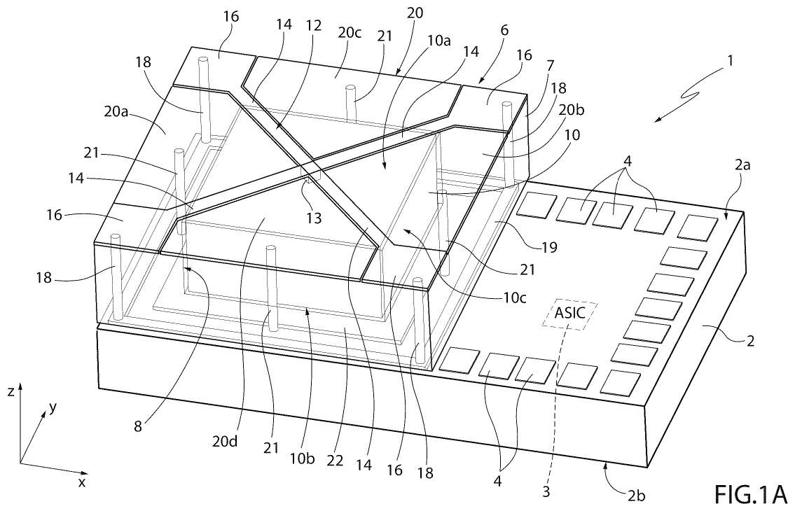

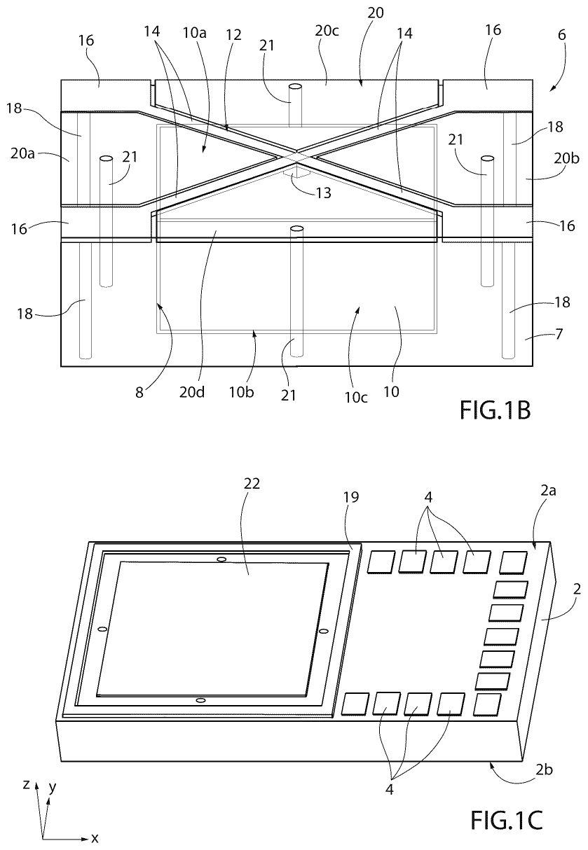

Referring to FIGS. 1A-1C, a sensor device, generally indicated by 1, in particular a microelectromechanical (MEMS) motion sensor device, comprises a base substrate 2, formed in a die of semiconductor material, for example silicon.

The base substrate 2 has a front surface 2a lying in a horizontal plane xy and a rear surface 2b, opposite to the front surface 2a along a vertical axis z, orthogonal to the horizontal plane xy.

The base substrate 2 integrates, in a manner not illustrated in detail, an electronic circuit 3 of the ASIC (Application Specific Integrated Circuit) type, configured to carry out suitable processing and to output electrical signals indicative of the quantity to be sensed, in particular of a first and a second component of this quantity along a first and a second axes, for example a first and a second horizontal axes x, y defining the aforementioned horizontal plane xy; and of a third component along a third axis, for example the vertical axis z.

Above the front surface 2a, the base substrate 2 has a plurality of electrical connection pads 4, for connecting the sensor device 1 with an external environment (for example with a control unit of an external electronic system, for providing output electrical signals and possibly receiving input signals and/or commands).

The sensor device 1 comprises, above the base substrate 2, a sensing structure 6, which includes a housing element, in particular a frame element 7, internally defining a cavity 8; for example, this frame element 7 may have a ring shape with a square (or rectangular or generically polygonal) cross-section parallel to the horizontal plane xy and a desired thickness (or height) along the vertical axis z.

According to one aspect of the present solution, the sensing structure 6 comprises, inside the cavity 8, a single mobile mass (or proof mass) 10, arranged in a suspended arrangement at a certain distance from the front surface 2a of the base substrate 2 and from internal walls of the aforementioned frame element 7.

In particular, this mobile mass 10 is centrally arranged inside the cavity 8, has a lower surface 10b facing at a distance the upper surface 2a of the base substrate 2; an upper surface 10a, opposite to the lower surface 10b along the vertical axis z; and lateral surfaces 10c facing corresponding internal walls of the frame element 7.

For example, this mobile mass 10 has a generically parallelepiped shape, with a square, rectangular, or generically polygonal cross-section in the horizontal plane xy.

The sensing structure 6 also comprises an elastic supporting arrangement 12, arranged above the mobile mass 10, with main extension (in a neutral, i.e., unstressed, condition) in a plane overlying the same mobile mass 10 with respect to the vertical axis z and parallel to the horizontal plane xy.

The elastic supporting arrangement 12 is configured to elastically support the mobile mass 10 inside the cavity 8, suspended above the base substrate 2.

The elastic supporting arrangement 12 is mechanically coupled to the mobile mass 10, centrally thereto, by a coupling element 13, having an extension along the vertical axis z (much smaller than the height or thickness of the mobile mass 10 along the same vertical axis z).

In particular, the mobile mass 10 has a central axis of symmetry parallel to the vertical axis z and the aforementioned coupling element 13 extends along this central axis of symmetry, between the upper surface 10a of the mobile mass 10 (which faces the elastic supporting arrangement 12) and the same elastic supporting arrangement 12.

The mobile mass 10 therefore has a center of gravity (or barycenter) arranged in a different plane with respect to the plane where the elastic supporting arrangement 12 lies (in the neutral condition), at a certain distance with respect to the same clastic supporting arrangement 12 along the vertical axis z.

This elastic supporting arrangement 12 is configured to allow movements due to inertial effect of the mobile mass 10 inside the cavity 8 in response to the quantity to be sensed, in particular: a first sensing movement, in response to a first component of the quantity to be sensed, for example along the first horizontal axis x of the horizontal plane xy; a second sensing movement, in response to a second component of the quantity to be sensed, for example along the second horizontal axis y of the horizontal plane xy; and a third sensing movement, for example in response to a third component of the quantity to be sensed along the vertical axis z.

In greater detail, in the embodiment illustrated in FIGS. 1A and 1C, the elastic supporting arrangement 12 comprises four elastic elements 14 having a linear main extension (and a smaller extension in the thickness direction, along the vertical axis z) arranged as a cross and aligned, in the example, diagonally with respect to the mobile mass 10. In particular, the elastic elements 14 are aligned in pairs, parallel to the diagonals of the cross-section of the mobile mass 10 in the horizontal plane xy; in other words, these elastic elements 14 extend at a certain angle (for example equal to 45°) with respect to the aforementioned first and second horizontal axes x, y.

The same elastic elements 14 may, alternatively, be of a folded, rather than linear, type with a generally “S” or serpentine shape.

The elastic elements 14 are joined centrally, at the coupling element 13; each elastic clement 14 therefore extends, in a manner suspended above the cavity 8, from the coupling element 13 towards a respective anchoring element 16, coupled integrally to the frame element 7 externally with respect to the mobile mass 10, at a respective corner of this frame element 7.

In the illustrated embodiment, the anchoring elements 16 have a substantially square (or generically polygonal) shape in a cross-section parallel to the horizontal plane xy and extend in the same plane as the aforementioned elastic elements 14.

The anchoring elements 16 are electrically coupled to the front surface 2a of the base substrate 2 by respective first electrical coupling elements 18, of conductive material, having a columnar shape and extending through the frame element 7 (in an insulated manner with respect to the same frame element 7, for example being formed in specific holes or through vias, so-called TSV—Through Silicon Vias) up to reaching the aforementioned front surface 2a.

In the illustrated embodiment, a conductive ring 19 is formed on the front surface 2a of the substrate 2 and surrounds in a continuous manner the mobile mass 10 (in the horizontal plane xy); the aforementioned first electrical coupling elements 18 are mechanically and electrically coupled to this conductive ring 19. In use, the mobile mass 10 may thus be biased to a suitable biasing voltage at which the conductive ring 19 is set; for example, the mobile mass 10 may be set at a reference voltage, for example at a ground of the electronic circuit 3 formed in the base substrate 2.

This conductive ring 19 may also provide mechanical bonding between the sensing structure 6 and the base substrate 2.

The aforementioned sensing structure 6 also comprises a first electrode arrangement 20, arranged above the mobile mass 10 with respect to the base substrate 2 and the vertical axis z.

In the illustrated embodiment, this first electrode arrangement 20 has main extension in the plane overlying the mobile mass 10 with respect to the vertical axis z and parallel to the horizontal plane xy, where the clastic supporting arrangement 12 lies in neutral or rest condition.

As will be described in detail, the first (top) electrode arrangement 20 is capacitively coupled to the mobile mass 10 to provide sensing of the first and second components of the quantity to be sensed, for example along the first and the second horizontal axes x, y.

Furthermore, the sensing structure 6 comprises a second electrode arrangement 22, arranged below the mobile mass 10, formed on the base substrate 2, with main extension on the corresponding front surface 2a.

As will be described in detail, this second (bottom) electrode arrangement 22 is capacitively coupled to the mobile mass 10 to provide sensing of the third component of the quantity to be sensed, for example along the vertical axis z.

In greater detail, the first electrode arrangement 20 comprises: a first pair of electrodes 20a, 20b aligned along the first horizontal axis x and arranged on opposite sides with respect to the second horizontal axis y and to the coupling element 13; and a second pair of electrodes 20c, 20d aligned along the second horizontal axis y and arranged on opposite sides with respect to the first horizontal axis x and to the coupling element 13.

Each of the aforementioned electrodes 20a-20d is arranged between a respective pair of the aforementioned elastic elements 14 and the respective anchoring elements 16 (at a certain separation distance from the same elastic elements 14 and anchoring elements 16), with a central portion (with a substantially triangular shape in the horizontal plane xy, in the embodiment illustrated in FIGS. 1A and 1C) suspended in cantilever fashion above the mobile mass 10 and a peripheral or edge portion (with a substantially rectangular shape in the horizontal plane xy in the same embodiment) supported by the frame element 7.

Each of the electrodes 20a-20d is also electrically coupled to the front surface 2a of the base substrate 2 by a respective second electrical coupling element 21, of conductive material, having a columnar shape and extending through the frame element 7 (in an insulated manner with respect to the same frame element 7, for example being formed in a specific hole or through via) up to reaching the aforementioned front surface 2a.

In particular, each of the second electrical coupling elements 21 is connected at the bottom to a conductive pad or track (not illustrated here in detail) formed at the front surface 2a of the base substrate 2 (or buried inside a surface portion of the same base substrate 2), to allow biasing of the respective electrode 20a-20d to a desired biasing voltage.

The first electrode arrangement 20 and the elastic supporting arrangement 12 thus close at the top the cavity 8 where the mobile mass 10 is arranged.

The second electrode arrangement 22 comprises an electrode arranged on the upper surface 2a of the base substrate 2, below the mobile mass 10 and facing the lower surface 10b of the same mobile mass 10. In the embodiment illustrated in FIGS. 1A and 1C, this electrode has a substantially square shape in the horizontal plane xy.

From what has been discussed and from what has been illustrated in the aforementioned FIGS. 1A-1C, it is therefore evident that the sensing structure 6 has complete symmetry, with respect to the first and second horizontal axes x, y (i.e., in the horizontal plane xy) and with respect to the vertical axis z.

In a manner not illustrated, the sensor device 1 may further comprise a cover, for example in epoxy resin, designed to be coupled on the front surface 2a of the base substrate 2 (or on part of this front surface 2a), in particular above the sensing structure 6, in order to hermetically close and protect the same sensing structure 6 from the external environment.

During operation, a component of the quantity to be sensed along the first horizontal axis x causes, due to inertial effect, a rotation of the mobile mass 10 outside the horizontal plane xy, around the second horizontal axis y, and a resulting movement of the same mobile mass 10 towards a first electrode (for example, the electrode 20a) of the first pair of electrodes 20a, 20b and a corresponding movement away from a second electrode (for example, from the electrode 20b) of the same first pair of electrodes 20a, 20b, with a resulting differential capacitive variation ±ΔC between the sensing capacitors formed between the mobile mass 10 and the aforementioned electrodes.

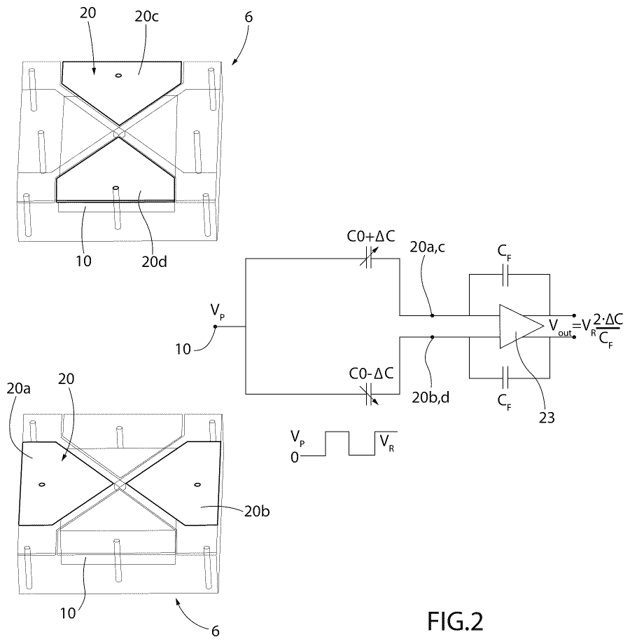

By adopting a differential sensing scheme, as shown schematically in FIG. 2, with the mobile mass 10 biased to a potential V_{P} (having in the example a square-wave trend, between 0 V and a desired value Vᵣ), an output voltage Vₒᵤₜ may thus be obtained which is indicative of the aforementioned capacitive variation ΔC and, therefore, of the value of the component of the quantity to be sensed along the first horizontal axis x.

As shown in FIG. 2, this output voltage Vₒᵤₜ may be provided between the output terminals of an operational amplifier 23 in a differential configuration, having differential input terminals connected to a respective one of the aforementioned electrodes 20a, 20b of the first pair and receiving a respective capacitive variation with respect to a fixed value C₀, C0+ΔC (a feedback capacitor C_{F} being connected between each output terminal and a respective input terminal).

In a corresponding manner, a component of the quantity to be sensed along the second horizontal axis y causes, due to inertial effect, a respective rotation of the mobile mass 10 outside the horizontal plane xy, around the first horizontal axis x, and a resulting movement of the same mobile mass 10 towards a first electrode (for example, the electrode 20c) of the second pair of electrodes 20c, 20d and a corresponding movement away from a second electrode (for example, from the electrode 20d) of the same second pair of electrodes 20c, 20d, with a resulting respective differential capacitive variation ±ΔC.

By adopting the same differential sensing and biasing scheme (shown in the aforementioned FIG. 2), an output voltage Vₒᵤₜ may thus be obtained, which is indicative of the differential capacitive variation ΔC and, therefore, of the value of the component of the quantity to be sensed along the second horizontal axis y.

Furthermore, a component of the quantity to be sensed along the vertical axis z causes, due to inertial effect, a displacement (translation) of the mobile mass 10 along the same vertical axis z and a resulting movement of the same mobile mass 10 towards the electrode of the second electrode arrangement 22, with a resulting capacitive variation ΔC.

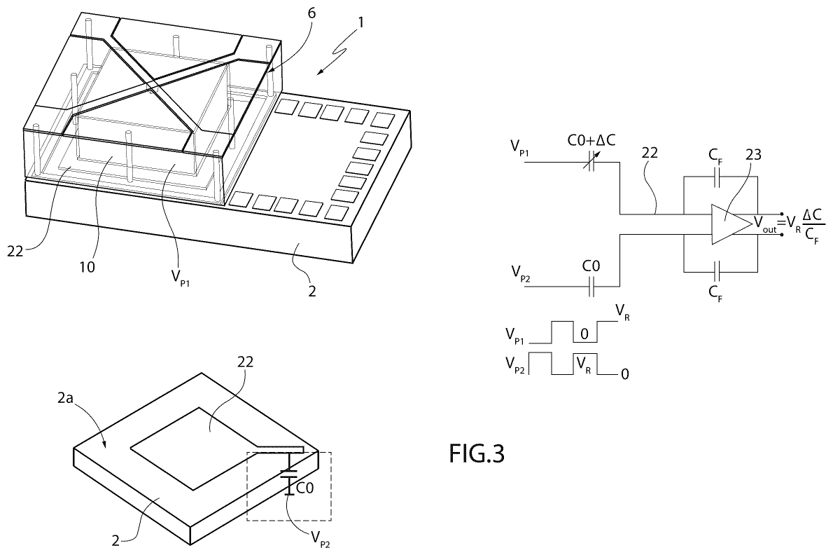

As shown schematically in FIG. 3, a single-ended sensing scheme may be adopted in this case, wherein only one sensing capacitor provides the output signal.

In this case, to avoid transferring also the fixed value component C₀ to the output, a fixed capacitor with a capacitance of the fixed value C₀ is added, which may be formed under the metallization of the same electrode of the second electrode arrangement 22, or in the electronic circuit 3 of the ASIC type.

The mobile mass 10 is here biased to a first biasing voltage V_{P1}, while the fixed capacitor is in this case biased to a second biasing voltage Vₚ₂, in phase opposition with respect to the first biasing voltage V_{P1}. The two different biasing voltages V_{P1}, V_{P2} are therefore opposite to each other (having in the example a square-wave trend in phase-opposition, between 0V and the desired value Vᵣ).

In this manner, also in this case, an output voltage Vₒᵤₜ may be obtained at the output terminals of the operational amplifier 23, which is indicative of the aforementioned capacitive variation ΔC and, therefore, of the value of the component of the quantity to be sensed along the vertical axis z.

As an alternative to this embodiment, a differential reading might again be used, assuming that two insulated halves of the mobile mass 10 are biased to the two different biasing voltages V_{P1}, V_{P2}.

In general, in case of accelerations with multiple directional components, the resulting motion will be the superposition of the movements that would occur with accelerations along the single axes x, y and z, which may be sensed as previously discussed.

The advantages of the proposed solution are clear from the preceding description.

In any case, it is emphasized that the sensor device 1 previously described has a simpler manufacturing compared to known solutions, owing to the presence of a monolithic sensing structure with a single mobile mass for sensing the components of the quantity to be detected, with a possible vertical integration with the electronics associated with the same sensing structure (in the form of an ASIC integrated into the base substrate).

A reduction in costs and also in the dimensions of the motion sensor device are clearly associated with the aforementioned simple manufacturing.

Advantageously, the sensing structure described and the sensing scheme adopted may allow, while sensing each of the components of the quantity to be sensed, rejection of the effects of the other components of the same quantity. In particular, the configuration of the elastic elements 14 of the elastic supporting arrangement 12 may be suitably designed to avoid mutual disturbances and interferences in sensing the acceleration components in the horizontal plane xy, along the first and the second horizontal axes x, y.

In general, the sensing structure described allows to obtain: a high detection sensitivity (owing to the fact that the high mechanical sensitivity is transformed into a high electrical sensitivity); a high full-scale; a high signal-to-noise ratio; and a substantial insensitivity to interferences between the axes.

The symmetry of the sensing structure also allows possible errors and drifts associated with thermal and mechanical effects to be limited.

The solution described allows for easy scalability of the detection sensitivity, by a suitable choice of the mechanical parameters of the sensing structure, such as for example the dimensions and shape of the mobile mass and the associated elastic supporting arrangement.

Furthermore, the sensor device may be made with known semiconductor material micromanufacturing techniques, including for example growth or deposition steps of materials such as polysilicon, silicon oxide, silicon nitride, through-via definition steps and bonding steps, for example by “glass-frit bonding”.

Finally, it is clear that modifications and variations may be made to what has been described and illustrated herein without thereby departing from the scope of the present disclosure, as defined in the attached claims.

In particular, it is highlighted that different configurations of the constitutive elements of the sensing structure 6 might be provided, such as for example of the mobile mass 10, the elastic elements 14 of the elastic supporting arrangement 12 (which might for example be of a folded, rather than linear, type, as previously indicated) and the corresponding anchoring elements 16.

Furthermore, different arrangements of the clastic elements 14 of the elastic supporting arrangement 12 may be provided, for example a cross-like configuration with the elastic elements 14 aligned in pairs along the first and the second horizontal axes x and y.

The arrangement of the anchoring elements 16 might also be different, for example they may be arranged centrally with respect to the side walls of the frame element 7 (rather than at the corners of the same frame element 7, as previously described).

A microelectromechanical motion sensor device (1) is summarized as including: a base substrate (2) having a front surface (2a) with extension in a horizontal plane (xy); and a sensing structure (6) arranged above the base substrate (2), configured to detect components of a motion quantity along respective sensing axes, wherein said sensing structure (6) includes: an housing element (7) integrally coupled above the front surface (2a) of said base substrate (2) and internally defining a cavity (8); a single mobile mass (10) arranged inside said cavity (8); an elastic supporting arrangement (12) arranged above the mobile mass (10), with main extension in a plane overlying the mobile mass (10) and configured to elastically support the mobile mass (10) inside the cavity (8), so as to be suspended above said front surface (2a) of the base substrate (2) and to perform, due to inertial effect, a respective sensing motion in response to each of said components of the motion quantity; and a sensing electrode arrangement (20, 22), capacitively coupled to the mobile mass (10) for sensing said components of the motion quantity.

Said housing element (7) is a frame element which surrounds said mobile mass (10); and wherein said elastic supporting arrangement (12) includes elastic elements (14) anchored to said frame clement and coupled to said mobile mass (10) centrally thereto by a coupling element (13), the coupling clement (13) having extension along a vertical axis (2) orthogonal to said horizontal plane (xy).

Said mobile mass (10) is centrally arranged inside said cavity (8) and has a lower surface (10b) facing at a distance the front surface (2a) of the base substrate (2) and an upper surface (10a) facing at a distance said elastic supporting arrangement (12), to which it is coupled by said coupling element (13); said mobile mass (10) having a barycenter (G) arranged at a distance along the vertical axis (2) with respect to the plane of extension of said clastic supporting arrangement (12).

Said elastic elements (14) are four in number, arranged as a cross, aligned in pairs and extending in a manner suspended above the cavity (8) from the coupling element (13) towards a respective anchoring element (16), coupled integrally to said frame element; said elastic elements (14) being joined centrally at said coupling element (13).

Said anchoring elements (16) are arranged at a respective corner of said frame clement and are electrically coupled to the front surface (2a) of the base substrate (2) by respective first electrical coupling elements (18), of conductive material, having a columnar shape and extending through the frame element in respective holes or through vias, up to reaching said front surface (2a).

Said elastic supporting arrangement (12) is configured to allow movements due to inertial effect of the mobile mass (10) inside the cavity (8), the movement including: a first sensing movement, in response to a first component of the motion quantity to be sensed along a first horizontal axis (x) of said horizontal plane (xy); a second sensing movement, in response to a second component of the motion quantity to be sensed along a second horizontal axis (y), which forms with the first horizontal axis (x) said horizontal plane (xy); and a third sensing movement, in response to a third component of the motion quantity to be sensed along the vertical axis (2).

Said sensing electrode arrangement (20, 22) includes: a first electrode arrangement (20), arranged above the mobile mass (10) with respect to the base substrate (2), having main extension in the plane overlying the mobile mass (10) where said elastic supporting arrangement (12) is formed, said first electrode arrangement (20) being capacitively coupled to said mobile mass (10) for sensing said first and second components of the motion quantity to be sensed; and furthermore a second electrode arrangement (22), arranged below the mobile mass (10), on the base substrate (2) and with main extension on the corresponding front surface (2a), the second electrode arrangement (22) being capacitively coupled to said mobile mass (10) for sensing said third component of the motion quantity to be sensed.

Said first electrode arrangement (20) includes: a first pair of electrodes (20a, 20b) aligned along the first horizontal axis (x) and arranged on opposite sides with respect to the second horizontal axis (y) and to the coupling element (13); and a second pair of electrodes (20c, 20d) aligned along the second horizontal axis (y) and arranged on opposite sides with respect to the first horizontal axis (x) and the coupling element (13).

Each of the electrodes (20a-20d) of said first and second pairs is arranged between a respective pair of said elastic elements (14), with a central portion suspended cantilevered above the mobile mass (10) and a peripheral portion supported by the frame element; and wherein each of said electrodes (20a-20d) is further electrically coupled to the front surface (2a) of the base substrate (2) by a respective second electrical coupling element (21), of conductive material, having a columnar shape and extending through the frame element in a respective hole or through via up to reaching said front surface (2a).

Said first electrode arrangement (20) and said elastic supporting arrangement (12) close at the top the cavity (8) where said mobile mass (10) is arranged.

Said second electrode arrangement (22) includes an electrode arranged on the upper surface (2a) of the base substrate (2), below and facing a respective half of the mobile mass (10).

Said mobile mass (10) is configured to perform, due to inertial effect: a rotation outside the horizontal plane (xy), in response to said first or said second component of the motion quantity and a resulting movement towards a first electrode of the first (20a, 20b) or second (20c, 20d) pair of electrodes and a corresponding movement away from a second electrode of the same first or second pair of electrodes, with a resulting differential capacitive variation (±ΔC); and a displacement along said vertical axis (2) in response to said third component of the motion quantity along the vertical axis (2) and a resulting movement towards the electrode of the second electrode arrangement (22), with a resulting capacitive variation (ΔC).

Said sensing structure (6) has a complete symmetry in said horizontal plane (xy) and with respect to a vertical axis (2), orthogonal to said horizontal plane (xy).

Said base substrate (2) integrates an ASIC—Application Specific Integrated Circuit—electronic circuit, coupled to said sensing structure (6) and configured to output electrical signals indicative of the components of the motion quantity to be sensed.

Said motion quantity to be sensed is an acceleration.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A microelectromechanical motion sensor device, comprising:
a base substrate having a front surface opposite a second surface along a first direction; and
a sensing structure on the front surface of the base substrate, the sensing structure configured to detect components of a motion quantity along a plurality of sensing axes,
wherein the sensing structure includes:
a housing element coupled to the front surface of the base substrate and including a cavity, the housing element including a frame element;
a single mobile mass arranged inside the cavity, the frame element surrounding the mobile mass;
an elastic supporting arrangement coupled to the mobile mass and extending in a plane opposite the mobile mass from the front surface along the first direction, the elastic supporting arrangement configured to elastically support the mobile mass inside the cavity, the mobile mass being suspended opposite the front surface of the base substrate, the mobile mass performing, due to an inertial effect, a respective sensing motion in response to each of the components of the motion quantity, the elastic supporting arrangement including:
a plurality of elastic elements anchored to the frame element; and
a coupling element with a first dimension along the first direction, the coupling element being coupled between the mobile mass and the plurality of elastic elements; and
a sensing electrode arrangement, capacitively coupled to the mobile mass for sensing the components of the motion quantity.

2. The device according to claim 1, wherein the mobile mass is centrally arranged inside the cavity and has a first surface facing and separated from the front surface of the base substrate along the first direction and a second surface facing and separated from the elastic supporting arrangement along the first direction, the second surface being coupled to the coupling element, the mobile mass having a barycenter arranged at a distance along the first direction from the plane of the elastic supporting arrangement.

3. The device according to claim 1, wherein the plurality of elastic elements includes four elastic elements, arranged as a cross, aligned in pairs and extending suspended opposite the cavity along the first direction from the coupling element towards a respective anchoring element of a plurality of anchoring elements, coupled to the frame element, each of the plurality of elastic elements being coupled centrally at the coupling element.

4. The device according to claim 3, wherein the plurality of anchoring elements are each arranged at a respective corner of the frame element and are electrically coupled to the front surface of the base substrate by respective first electrical coupling elements of conductive material having a columnar shape and extending along the first direction through the frame element in respective holes to the front surface.

5. The device according to claim 1, wherein the elastic supporting arrangement is configured to allow movements due to the inertial effect of the mobile mass inside the cavity, the movement including:
a first sensing movement, in response to a first component of the motion quantity to be sensed along a second direction transverse to the first direction;
a second sensing movement, in response to a second component of the motion quantity to be sensed along a third direction transverse to the first and second directions; and
a third sensing movement, in response to a third component of the motion quantity to be sensed along the first direction.

6. The device according to claim 5, wherein the sensing electrode arrangement comprises:
a first electrode arrangement, arranged above the mobile mass with respect to the base substrate, extending in the plane where the elastic supporting arrangement is formed, the first electrode arrangement being capacitively coupled to the mobile mass for sensing the first and second components of the motion quantity to be sensed; and
a second electrode arrangement, arranged opposite the mobile mass from the first electrode arrangement, on the base substrate, the second electrode arrangement being capacitively coupled to the mobile mass for sensing the third component of the motion quantity to be sensed.

7. The device according to claim 6, wherein the first electrode arrangement comprises:
a first pair of electrodes aligned along the second direction and arranged on opposite sides with respect to the coupling element; and
a second pair of electrodes aligned along the third direction and arranged on opposite sides with respect to the coupling element.

8. The device according to claim 7, wherein each of the electrodes of the first and second pairs is arranged between a respective pair of the elastic elements, with a central portion of each electrode suspended cantilevered opposite the mobile mass and a peripheral portion of each electrode supported by the frame element, and wherein each of the electrodes is further electrically coupled to the front surface of the base substrate by a respective second electrical coupling element, of conductive material, having a columnar shape and extending along the first direction through the frame element in a respective hole to the front surface.

9. The device according to claim 6, wherein the second electrode arrangement includes an electrode on the upper surface of the base substrate, facing a respective half of the mobile mass.

10. The device according to claim 5, wherein the mobile mass is configured to perform, due to the inertial effect:
a rotation outside a plane defined by the second and third directions, in response to the first or the second component of the motion quantity and a resulting movement towards a first electrode of the first or second pair of electrodes and a corresponding movement away from a second electrode of the same first or second pair of electrodes, with a resulting differential capacitive variation; and
a displacement along the first direction in response to the third component of the motion quantity along the first direction and a resulting movement towards the electrode of the second electrode arrangement, with a resulting capacitive variation.

11. The device according to claim 1, wherein the sensing structure has a complete symmetry in the plane defined by the second and third directions and with respect to an axis along the first direction.

12. The device according to claim 1, wherein the base substrate includes an ASIC (Application Specific Integrated Circuit) electronic circuit coupled to the sensing structure and configured to output electrical signals indicative of the components of the motion quantity to be sensed.

13. The device according to claim 1, wherein the motion quantity to be sensed is an acceleration.

14. A device, comprising:
a base substrate having a first surface; and
a sensing structure on the first surface, the sensing structure including:
a frame element with a cavity extending from the first surface of the base substrate partially through the frame element along a first direction;
a mobile mass in the cavity having a first surface opposite a second surface, the second surface of the base substrate being physically separated from the first surface of the mobile mass, the mobile mass being physically separated from a plurality of internal sidewalls of the cavity;
an elastic supporting arrangement extending along a first plane transverse to the first direction, the elastic supporting arrangement suspending the mobile mass away from the first surface; and
a coupling element directly coupled directly to the elastic supporting arrangement, physically separating the elastic supporting arrangement from the mobile mass along the first direction.

15. The device according to claim 14, wherein the elastic supporting arrangement further comprises a plurality of elastic elements extending in a cross within the first plane, the coupling element being at a center of the cross.

16. The device according to claim 15, wherein each elastic element extends from the coupling element to an anchoring element coupled to the frame element, each anchor being coupled to the first surface of the base substrate via an electric coupling element, the electric coupling element extending entirely through the frame element.

17. The device according to claim 16, wherein each electric coupling element is directly coupled to a conductive ring on the first surface of the base substrate.

18. A device, comprising:
a base substrate having a first surface; and
a sensing structure on the first surface, the sensing structure including:
a frame element with a cavity extending from the first surface of the base substrate partially through the frame element along a first direction;
a mobile mass in the cavity, physically separated from the first surface and from a plurality of internal sidewalls of the cavity;
a plurality of elastic elements extending along a first plane transverse to the first direction, the plurality of elastic elements suspending the mobile mass away from the first surface along the first direction;
a plurality of anchors, each coupled between a respective one of the plurality of elastic elements and the frame element;
a coupling element directly coupled directly to the plurality of elastic elements, the coupling element physically separating the plurality of elastic elements from the mobile mass along the first direction; and
a first plurality of electrical coupling elements extending through the frame element along the first direction, the first plurality of electrical coupling elements being coupled between a respective anchor of the plurality of anchors and the first surface of the base substrate.

19. The device according to claim 18, further comprising a first conductive ring on the first surface of the base substrate, each of the first plurality of electrical coupling elements being directly coupled between the respective anchor and the first conductive ring.

20. The device according to claim 19, further comprising:
a first plurality of electrodes extending within the first plane, each of the first plurality of electrodes being between a respective pair of elastic elements of the plurality of elastic elements;
a second plurality of electrical coupling elements extending entirely through the frame along the first direction; and
a conductive pad on the first surface of the base substrate, each of the second plurality of electrical coupling elements being directly coupled to both the conductive pad and to a respective electrode of the plurality of electrodes.
